(19) United States
(12) Patent Application Publication
(10) Pub. No.: US 2006/0076965 A1
(43) Pub. Date: Apr. 13, 2006

(54) Contact-free test system for semiconductor device

(76) Inventors: Young-Soo An, Gyeonggi-do (KR); Hun-Kyo Seo, Chungcheongnam-do (KR); Hyun-Seop Shim, Incheon Metropolitan City (KR); Jeong-Seon Kim, Gyeonggi-do (KR); Ki-Don Hong, Gyeonggi-di (KR); Tcherniak Valeri, Gyeonggi-do (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/147,437

(22) Filed: Jun. 8, 2005

(30) Foreign Application Priority Data
Oct. 12, 2004 (KR) 2004-0081308

(51) Int. Cl. G01R 31/305

(52) U.S. Cl. 324/751

(57) ABSTRACT

The present invention provides a contact-free test system for testing a semiconductor device. The contact-free test system comprises a test signal member applying a test signal to the semiconductor device, an electronic beam radiator generating a first electronic beam and radiating it to an area of the semiconductor device, a detector to detect a second electronic beam reflected from the semiconductor device, and a comparator to compare the test signal with the second electronic beam.

### BACKGROUND OF THE INVENTION

1. Field of the Invention

The present invention generally relates to a test system for a semiconductor device. More particularly, the present invention generally relates to a contact-free test system used to test a semiconductor device.

A claim of priority is made to Korean Patent Application No. 2004-81308, filed on Oct. 12, 2004, the contents of which are incorporated by reference.

2. Description of the Related Arts

Inspections are conducted on semiconductor devices to test electrical characteristics following various fabrication processes, and to sort the semiconductor devices as being either non-defective or defective. An electrical test signal generated by a testing apparatus, for example a tester, is applied to a semiconductor device package to test whether the semiconductor device operates normally.

A test socket is used as an intermediate medium to connect the tester to the semiconductor device, so that the tester may transmit one or more test signals to the semiconductor device. In other words, the electrical characteristics of the semiconductor device are checked by an exchange of test signals between the tester and the semiconductor device. External connection terminals of the semiconductor device are in direct contact with terminals in the test socket. The test socket is usually inserted into a test board associated with the tester. Accordingly, a conventional inspection is performed while the semiconductor device is in direct contact with the test socket.

Thus a plurality of physical contact points generally exist between the tester and the semiconductor device when the above inspection is performed. However, there are contact resistances between the test board and the test socket, and between the test socket and the semiconductor device, because these respective electrical connections are made via distinct physical contacts.

Contact resistance is one cause for poor reliability in test results for semiconductor devices operating at high speeds. The contact resistance is a source of noise. Therefore, test socket terminals are generally plated with gold (Au) to reduce the intrinsic and contact resistances associated with the test sockets. However, the test sockets require frequent replacement, because the gold plating easily wears out during repetitive use of the test socket. The rate at which the test sockets must be replaced further increases with the operating frequency of the semiconductor devices being tested.

A test socket having minimal contact resistance and reduced signal path length between the semiconductor device and test board should be used to inspect semiconductor devices operating at a speed above 1 GHz. However, contact-type test sockets have limitations when testing semiconductor devices operating at speeds greater than several tens of GHz or higher. Therefore, there is a limit in using a contact test socket with semiconductor devices operating at high speeds.

### SUMMARY OF THE INVENTION

In one aspect, the present invention provides a test system capable of testing semiconductor devices operating at speed of several tens of GHz or higher.

In one embodiment, the present invention provides a test signal member adapted to provide a standard wave pattern, an electronic beam generator to send a first electronic beam to an area of a semiconductor device, a detector to detect a second electronic beam, wherein the second electronic beam is a reflection of the first electronic beam from the semiconductor device, and a comparator to determine whether the semiconductor device is defective or not by comparing a wave pattern of the second electronic beam with a standard wave pattern provided by the test signal member.

In another embodiment, the present invention provides a method of testing a semiconductor device by generating a standard wave pattern using a test signal member, sending a first electronic beam from an electronic beam generator to a semiconductor device, detecting a second electronic beam using a comparator, wherein the second electronic beam is a reflection of the first electronic beam from the semiconductor device, and comparing a wave pattern of the second electronic beam with the standard wave pattern using a comparator.

### BRIEF DESCRIPTION OF THE DRAWINGS

FIG. 1 is a schematic diagram illustrating a contact-free test system for a semiconductor device according to an embodiment of the present invention.

FIG. 2 is a flow chart illustrating a method of testing a semiconductor device utilizing the system of FIG. 1.

FIG. 3 is a test result wave patterns.

### DETAILED DESCRIPTION

The present invention will now be described more fully hereinafter with reference to the accompanying drawings.

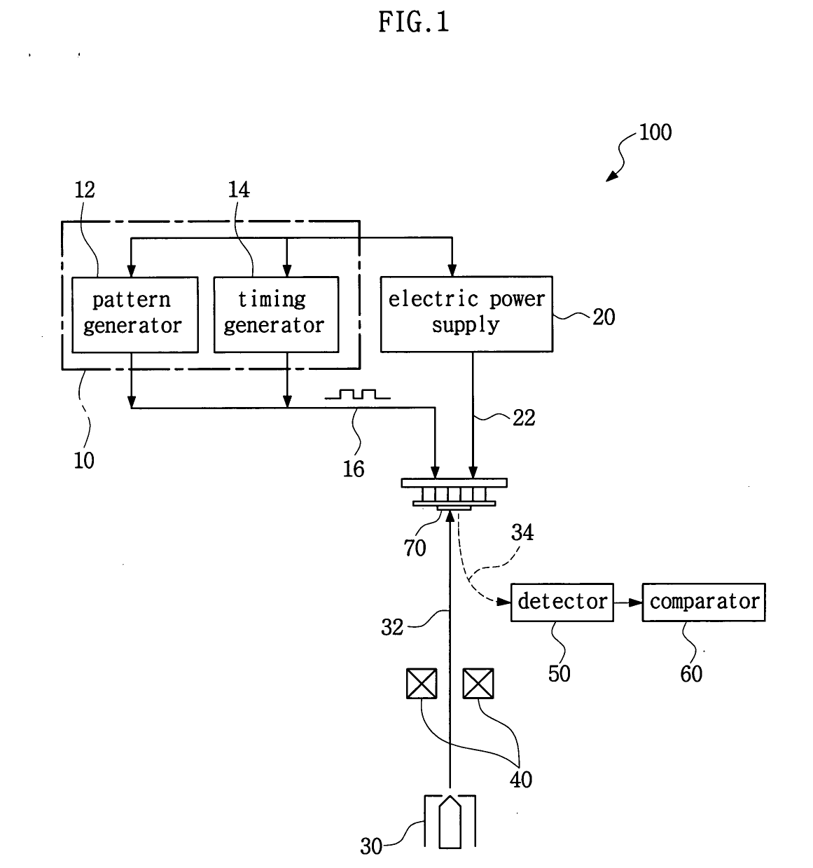

FIG. 1 illustrates a contact-free test system 100 used to test a semiconductor device according to an embodiment of the present invention. In the present invention, an electronic beam radiator 30 is adapted to send a first electronic beam 32 to a semiconductor device 70, a detector 50 analyzes a second (reflected) electronic beam 34, and a comparator 60 determines whether or not semiconductor device 70 is defective, i.e., whether it passes or fails a defined quality control test. In this manner, test system 100 is able to evaluate semiconductor device 70 without any physical connection to semiconductor device 70. Contact-free test system 100 further includes a test signal member 10 comprising a pattern generator 12 and a timing generator 14. Test signal member 10 inputs a test signal 16 to semiconductor device 70. Electronic beam radiator 30 generates first electronic beam 32 and sends it to semiconductor device 70. Detector 50 detects second electronic beam 34, which is a reflection of first test signal 32. Second electronic 34 may comprise some indication of test signal 16 as it is reflected from semiconductor device 70. Comparator 60 determines whether or not semiconductor device 70 is defective by comparing a normal (standard) wave pattern generated from test signal 16 with a wave pattern apparent in second electronic beam 34.

Wave patterns generated by pattern generator 12 and by timing generator 14 are converted into test signal 16. Electrical power 22 from an electric power source 20 and test signal 16 are supplied together to semiconductor device 70 using conventional methods.

Electronic beam radiator 30 generates first electronic beam 32 and sends it to semiconductor device 70. First electronic beam 32 accelerates while it passes through a scan coil 40 prior to reaching semiconductor device 70. Scan coil 40 assists in precisely directing first electronic beam 32 to a specific area of semiconductor device 70.

The specific area of semiconductor device 70, which receives first electronic beam 32, is preferably a chip pad, an external terminal, or a detecting circuit. In the context of the present invention, semiconductor device 70 may be a bare chip, or a packaged chip.

Comparator 60 determines whether or not semiconductor device 70 is defective by comparing the wave pattern of second electronic beam 34 with the output wave pattern of test signal 16. Test signal 16 should be apparent in second electronic beam 34, and therefore discernable within second electronic beam 34 is detected by detector 50 and comparator 60. Optionally, test signal 16 may be sent directly to comparator 60 to be compared with second electronic beam 34. In other words, test signal 16 may bypass semiconductor device 70.

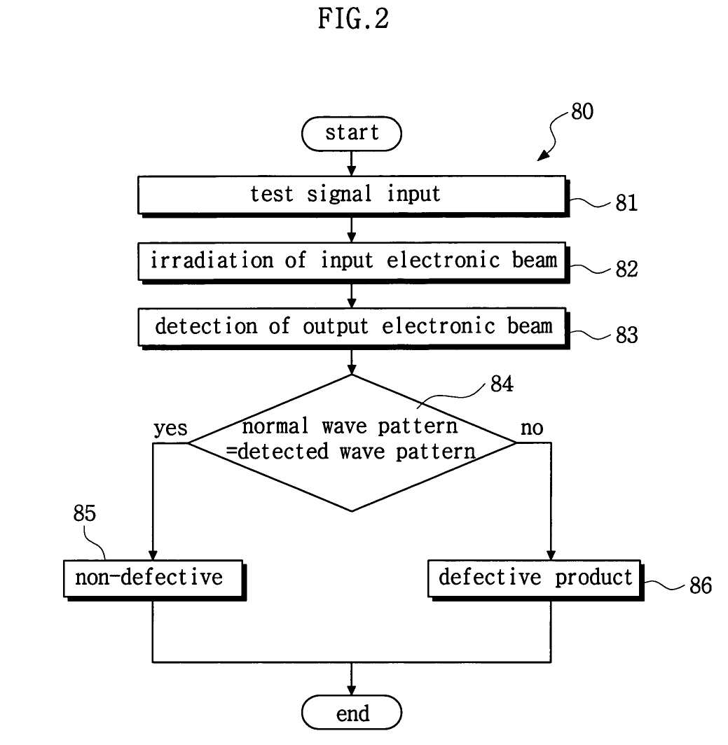

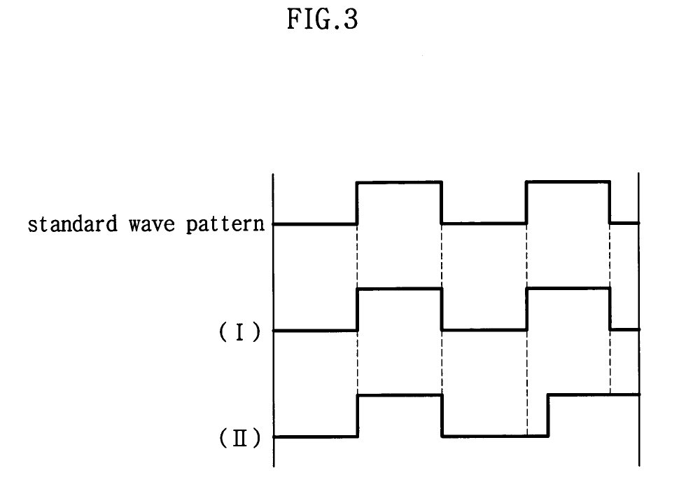

FIG. 2 is a flow chart illustrating a test method 80 utilizing test system 100 of FIG. 1. FIG. 3 illustrates test result wave patterns.

First, electrical power 22 and test signal 16 are supplied to semiconductor device 70 (81). That is, wave patterns generated by pattern generator 12 and timing generator 14 are converted into test signal 16 and sent to semiconductor device 70. As described above, test signal 16 may be optionally sent directly to comparator 60.

First electronic beam 32 is then sent to semiconductor device 70 (82). That is, electronic beam radiator 30 sends first electronic beam 32 to a region on semiconductor device 70.

Then, second electronic beam 34 reflected from semiconductor device 70 is detected by detector 50 (83).

Finally, a determination of whether semiconductor device 70 is acceptable is made by comparing a standard wave pattern corresponding to test signal 16 and the detected wave pattern of second electronic beam 34 (84). That is, comparator 60 determines whether semiconductor device 70 is defective by comparing the standard wave pattern corresponding to test signal 16 with the detected wave pattern of second electronic beam 34.

As shown in FIG. 3, a semiconductor device is classified as non-defective if the detected wave pattern (I) is identical to the standard wave pattern (85). A semiconductor device is classified as defective if the detected wave pattern (II) is not identical to the standard wave pattern (86).

The present invention has been disclosed by the preferred embodiments shown in this specification and accompanying drawings. It should be understood to the ordinary person skilled in the art that various changes or modifications of the embodiments are possible without departing from the scope of the present invention.

What is claimed is:

1. A contact-free test system, comprising:
a test signal member adapted to provide a standard wave pattern;
an electronic beam generator to send a first electronic beam to an area of a semiconductor device;
a detector to detect a second electronic beam, wherein the second electronic beam is a reflection of the first electronic beam from the semiconductor device; and
a comparator to determine whether the semiconductor device is defective or not by comparing a wave pattern of the second electronic beam with a standard wave pattern provided by the test signal member.

2. The tester of claim 1, wherein the test signal member comprises a pattern generator and a timing generator.

3. The tester of claim 1, further comprising an electric power source to supply electrical power to the semiconductor device.

4. The tester of claim 1, further comprising a signal converter to convert the standard wave pattern generated by the test signal member to a test signal.

5. The tester of claim 1, further comprising a scan coil to direct the first electronic beam onto an area of the semiconductor device.

6. The tester of claim 5, wherein the area is a chip pad, an external terminal, or a detecting circuit.

7. A method of testing a semiconductor device using a contact-free test system, comprising:
generating a standard wave pattern using a test signal member;
sending a first electronic beam from an electronic beam generator to a semiconductor device;
detecting a second electronic beam using a comparator, wherein the second electronic beam is a reflection of the first electronic beam from the semiconductor device; and
comparing a wave pattern of the second electronic beam with the standard wave pattern using a comparator.

8. The method of claim 7, wherein the standard wave pattern is converted into a test signal.

9. The method of claim 8, wherein the test signal is sent to the semiconductor device, and the second beam further includes the standard wave pattern.

10. The method of claim 8, wherein the test signal is sent to the comparator, and the comparator compares the test signal with the second electronic beam.

11. The method of claim 7, wherein the test signal member comprises a pattern generator and a timing generator.

12. The method of claim 7, further comprising a scan coil to direct the first electronic beam onto an area of the semiconductor device.

13. The method of claim 12, wherein the area is a chip pad, an external terminal, or a detecting circuit.
